(19) United States
(12) Patent Application Publication
(10) Pub. No.: US 2026/0231591 A1
(43) Pub. Date: Aug. 6, 2026

(54) APPLICATION TAILORED PHOTOVOLTAIC DEVICES AND METHODS EXPLOITING MIXED CATION PEROVSKITES

(71) Applicants: IVY MAWUSI ASUO, MONTREAL (CA); IBRAHIMA KA, ST. HUBERT (CA); RIAD NECHACHE, MONTREAL (CA)

(72) Inventors: IVY MAWUSI ASUO, MONTREAL (CA); IBRAHIMA KA, ST. HUBERT (CA); RIAD NECHACHE, MONTREAL (CA)

(21) Appl. No.: 19/151,185

(22) PCT Filed: Jan. 26, 2024
(86) PCT No.: PCT/CA2024/050090

§ 371 Date: Jul. 25, 2025

Related U.S. Application Data
(60) Provisional application No. 63/481,825, filed on Jan. 27, 2023.

(51) Int. Cl. H10K 30/40; H10K 71/00

(52) U.S. Cl. CPC H10K 30/40; H10K 71/851

(57) ABSTRACT

Organic-inorganic halide perovskite (OIHP) materials have recently attracted interest due to their promising material properties, low complexity solution based processability and low material cost for large area photovoltaic devices. However, environmental stability has been limited to date as well OIHP material tailoring to the emission characteristics of the illuminating optical source(s) thereby limiting efficiency in indoor environments with incandescent, fluorescent or LED sources. Accordingly, the inventors have established perovskites of composition FA_{X}Cs_{Y}Pb(I_{1-Z}Cl_{Z}) where X, Y and Z range from 0.00001 to 3 respectively which provide improved environmental stability and absorption tailoring to illuminating optical source(s) as well as opto-electronic devices exploiting such doped hybrid perovskite materials.

This patent application claims the benefit of priority as a 371 national phase entry application of PCT/CA2024/050090 filed Jan. 26, 2024; which itself claims the benefit of priority from U.S. Patent Application 63/481,825 filed Jan. 27, 2023; the entire contents of which are incorporated herein by reference.

### FIELD OF THE INVENTION

This patent application relates to perovskite materials and photovoltaic modules using said perovskite materials and more particularly to perovskite materials tailored for use in indoor applications with improved environmental stability and reduced manufacturing complexity as well as opto-electronic devices exploiting such doped hybrid perovskite materials.

### BACKGROUND OF THE INVENTION

Organic-inorganic halide perovskite (OIHP) materials have recently attracted interest due to their promising material properties, low complexity solution based processability and low material cost which makes them compatible to the requirements for large area photovoltaic devices.

Additionally, high photon absorption, carrier mobility, and tunable band gap of OIHP materials make them particularly advantageous for applications such as optical displays, light emitting diodes (LEDs), photovoltaic (PV) cells (e.g. solar cells, tandem solar cells) and photodetectors. It would be beneficial to establish doped hybrid perovskite materials that can be tuned towards particular deployment environments such as indoor or outdoor, for example.

Other aspects and features of the present invention will become apparent to those ordinarily skilled in the art upon review of the following description of specific embodiments of the invention in conjunction with the accompanying figures.

### SUMMARY OF THE INVENTION

It is an object of the present invention to mitigate limitations within the prior art relating to perovskite materials and photovoltaic modules using said perovskite materials and more particularly to perovskite materials tailored for use in indoor applications with improved environmental stability and reduced manufacturing complexity as well as opto-electronic devices exploiting such doped hybrid perovskite materials.

In accordance with an embodiment of the invention there is provided a method of forming a photovoltaic device comprising:
depositing one or more first layers of the photovoltaic device to form a lower portion of the photovoltaic device;
depositing a perovskite film to form an active layer of the optoelectronic device; and
depositing one or more second layers of the optoelectronic device to form an upper portion of the optoelectronic device; wherein
the perovskite film has the composition FA_{X}Cs_{Y}Pb(I_{1-Z}Cl_{Z}) where X, Y and Z range from 0.00001 to 3 respectively.

In accordance with an embodiment of the invention there is provided a method of forming a precursor comprising:
dissolving a number of individual components in one or more organic solvents; and
dissolving an additive with the number of individual components; wherein the precursor provides for a perovskite film when processed onto a substrate;
the precursor is a double cation perovskite solution;
the precursor allows formation of perovskite films in ambient conditions; and
the perovskite film has the composition FA_{X}Cs_{Y}Pb(I_{1-Z}Cl_{Z}) where X, Y and Z range from 0.00001 to 3 respectively.

In accordance with an embodiment of the invention there is provided a device comprising: a perovskite film forming an active layer of the device; wherein the perovskite film has the composition FA_{X}Cs_{Y}Pb(I_{1-Z}Cl_{Z}) where X, Y and Z range from 0.00001 to 3 respectively.

In accordance with an embodiment of the invention there is provided a method of fabricating a photovoltaic device comprising:
forming a lower conductive layer;
forming an active layer upon the lower conductive layer which generates an electrical current in dependence upon optical illumination within a predetermined wavelength range illuminating the active layer;
forming an upper conductive layer upon the active layer;
establishing a series of first scribe lines to isolate a first plurality of regions where each first scribe line of the series of first scribe lines penetrates down through the lower conductive layer;
establishing a series of second scribe lines to isolate a second plurality of regions where each second scribe line of the series of second scribe lines penetrates down through at least the active layer but not the lower conductive layer; and
establishing a series of third scribe lines to isolate a third plurality of regions where each third scribe line of the series of third scribe lines penetrates down through the active layer and upper conductive layer.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 depicts a schematic representation of a multilayer heterostructure architecture of an exemplary perovskite based solar cell exploiting OIHP materials according to embodiments of the invention;

FIG. 2 depicts a scanning electron microscope image of the surface morphology of a perovskite film according to an embodiment of the invention together with an X-ray diffraction pattern and absorbance measurements of perovskite films according to embodiments of the invention made with varying composition;

FIG. 3 depicts a cross-sectional view of a perovskite film based photovoltaic module according to an embodiment of the invention depicting the different scribe lines employed in the formation of the module;

FIG. 4A depicts plan views of a perovskite film based photovoltaic module depicting a prior art scribe pattern together with scribe patterns according to embodiments of the invention;

FIG. 4B depicts plan views of a perovskite film based photovoltaic module depicting a prior art scribe pattern together with scribe patterns according to embodiments of the invention;

FIG. 5 depicts plan views of a perovskite film based photovoltaic module depicting scribe patterns according to embodiments of the invention;

FIG. 6 depicts current-voltage characteristic curves of perovskite film based photovoltaic modules according to embodiments of the invention;

FIG. 7 depicts the irradiance spectra of the lamp used for the current-voltage measurements in FIG. 6 at different illumination levels together with the evolution of open circuit voltage and power conversion efficiency as a function of the bromide content of the perovskite films;

FIG. 8 depicts plan and cross-section views of a perovskite film based photovoltaic module employing laser scribing rather than mechanical scribing;

FIG. 9 depicts current density versus voltage for a perovskite film based photovoltaic module according to an embodiment of the invention;

FIG. 10 depicts current density versus voltage curves for a perovskite film based photovoltaic module at different illumination levels according to an embodiment of the invention;

FIG. 11 depicts extracted open circuit voltage and power conversion efficiency under varying illumination levels for a perovskite film based photovoltaic module according to an embodiment of the invention;

FIG. 12 depicts ultraviolet photoelectron spectroscopy spectra for perovskite inks according to embodiments of the invention with and without cesium bromide; and

FIG. 13 depicts the evolution of power conversion efficiency, V_{oc}, J_{sc}, and fill factor of the perovskite film-based photovoltaic module under continuous illumination according to an embodiment of the invention.

### DETAILED DESCRIPTION

The present invention is directed to perovskite materials and photovoltaic modules using said perovskite materials and more particularly to perovskite materials tailored for use in indoor applications with improved environmental stability and reduced manufacturing complexity as well as opto-electronic devices exploiting such doped hybrid perovskite materials.

The ensuing description provides representative embodiment(s) only, and is not intended to limit the scope, applicability or configuration of the disclosure. Rather, the ensuing description of the embodiment(s) will provide those skilled in the art with an enabling description for implementing an embodiment or embodiments of the invention. It is understood that various changes can be made in the function and arrangement of elements without departing from the spirit and scope as set forth in the appended claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment”, “an embodiment”, “some embodiments” or “other embodiments” means that a particular feature, structure, or characteristic described in connection with the embodiments is included in at least one embodiment, but not necessarily all embodiments, of the inventions. The phraseology and terminology employed herein are not to be construed as limiting but are for descriptive purposes only. It is to be understood that where the claims or specification refer to “a” or “an” element, such reference is not to be construed as there being only one of that element. It is to be understood that where the specification states that a component feature, structure, or characteristic “may”, “might”, “can” or “could” be included, that particular component, feature, structure, or characteristic is not required to be included.

Reference to terms such as “left”, “right”, “top”, “bottom”, “front” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users.

Reference to terms “including”, “comprising”, “consisting” and grammatical variants thereof do not preclude the addition of one or more components, features, steps, integers or groups thereof and that the terms are not to be construed as specifying components, features, steps or integers. Likewise, the phrase “consisting essentially of”, and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional elements.

### Exemplary Photovoltaic Cell Geometry

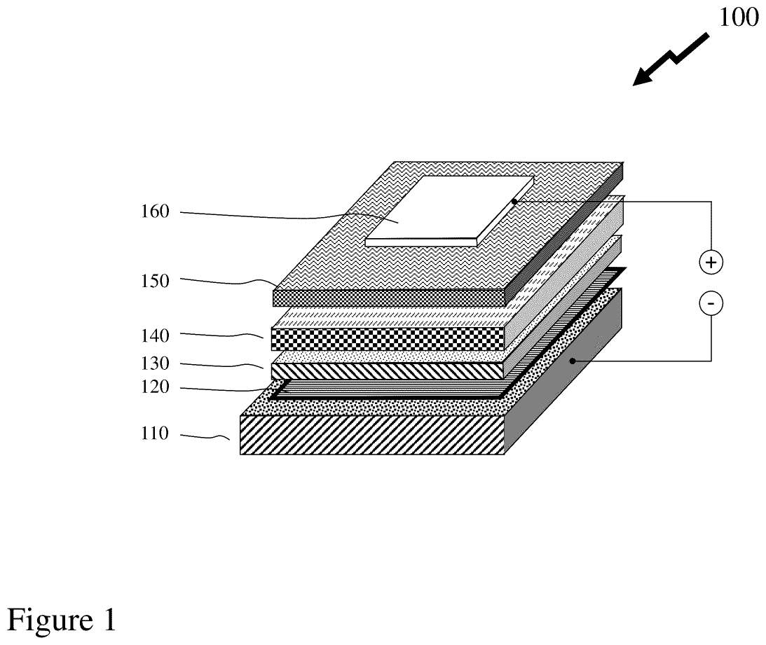

Within the following description with respect to the manufacturing of OIHP films and devices according to embodiments of the invention the experimental device results are presented with respect to a typical photovoltaic (PV) application based upon a multilayer heterostructure architecture such as that depicted in FIG. 1.

FIG. 1 depicts a full-stack multilayered structure of a three-dimensional (3D) perovskite solar cell (PSC) 100 showing each layer and junction. The 3D geometry comprises a stacked sequence of:
Lower Electrode 110;
Lower charge extracting structure comprising:
   Electron Transport Layer (ETL) 120, 130;
   Semiconductor material (e.g. titanium oxide (TiO₂), tin oxide (SnO₂), mesoporous titanium dioxide (MP-TiO₂)) 120, 130;
Perovskite semiconductor material (PVK) 140;
Upper charge extracting structure comprising:
   Hole Transport Layer (HTL) 150; and
Upper Electrode 160.

According to an embodiment of the invention the Lower Electrode 110 may comprise an electrically conductive material or an electrically conductive coating upon an insulating substrate. For example, an implementation of the latter being a glass or flexible substrate coated with fluorine-doped tin oxide (FTO).

According to an embodiment of the invention the Upper Electrode 160 may be a conductor such as a metal, an alloy, or a conductive material compatible with the material(s) employed in providing the HTL 150. For example, the Upper Electrode 160 may be gold, platinum, copper, indium tin oxide (ITO), or FTO.

Accordingly, the thin film of perovskite (PVK) 140 semiconductor material is disposed between a pair of charge extracting layers, namely an upper charge extracting structure comprising a hole transporting layer (HTL) 150 and a lower charge extracting structure comprising an electron transporting layer (ETL) with a semiconductor material 130 layer, such as mesoporous TiO₂ (MP-TiO₂) which provides an n-type semiconductor material, disposed between the ETL 120 and PE 140.

According to different designs for the PSC 100 the ETL 120 materials may, for example, be titanium dioxide (TiO₂), tin oxide (SnO₂) or [6,6]-phenyl-C61-butyric acid methyl ester (PCBM).

According to different designs for the PSC 100 the HTL 150 may, for example, be 2,2′,7,7′-Tetrakis-(N,N-di-4-methoxyphenylamino)-9,9′-spirobifluorene (Spiro-MeOTAD), copper (1) thiocyanate (CuSCN), copper (II) phthalocyanine (CuPC) and poly(3,4-ethylenedioxythiophene):polystyrene sulfonate (PEDOT:PSS).

Within embodiments of the invention as described and depicted below the inventors have established a new family of perovskite films having a composition FA_{X}Cs_{Y}Pb(I_{1-Z}Cl_{Z}) where X, Y and Z range from 0.00001 to 3 respectively. The inventors have further established variants wherein perovskite films according to embodiments of the invention comprising CsBr can operate without a HTL whilst perovskite films according to other embodiments of the invention without CsBr employ an HTL, e.g. CuPC.

Further, as will become evident with respect to the subsequent description the novel OIHP materials as established by the inventors employed in exemplary PSC 100 demonstrations are an advance upon the prior art in offering a path towards the realization highly efficient and ambient processable perovskite materials for low cost opto-electronic devices and low cost opto-electronic device applications. As will become evident, the low complexity and robust processing techniques that can be employed with the innovate perovskite materials allow for large area coatings to be achieved, allowing for solar cell and module fabrication and mass fabrication.

### Novel Perovskite Material and Manufacturing Methodology

Organic-inorganic halide perovskite materials have been known to be synthesized in a glove box since these materials are susceptible to degradation in the presence of moisture, oxygen, and high temperature. The inventors have previously described and reported doped perovskite films having a composition FA_{X}MA_{Y}CS_{Z}Pb_{Y}I_{M}SCN_{Q}Br_{N} where X, Y, Z, M, V, Q, N may each range between 0.0001 to 3 that can be processed under ambient conditions, see for example PCT/CA2020/050809 “Doped Mixed Cation Perovskite Materials and Devices Exploiting Same” published as WO/2020/248063.

As will become evident from the description below the inventors have established stable halide perovskite materials for perovskite films having a composition FA_{X}Cs_{Y}Pb(I_{1-Z}Cl_{Z}), where X, Y and Z range from 0.00001 to 3 respectively, where these halide perovskite materials can be processed in ambient atmospheric conditions. The halide perovskite materials having the composition FA_{X}Cs_{Y}Pb(I_{1-Z}Cl_{Z}), where X, Y and Z range from 0.00001 to 3 respectively, provide a tunable bandgap via compositional substitutions allowing the halide perovskite materials to be tailored for harvesting ambient light with different spectra. For example, a halide perovskite material may be tailored to ambient sunlight for external applications or it may be tailored to fluorescent, incandescent or light emitting diode (LED) sources for indoor applications. Other halide perovskite materials may be tailored to cover both indoor and outdoor environments.

Within the embodiments of the invention described below a low-cost carbon electrode based perovskite module with high performance is described providing a competitive solution for indoor photovoltaic devices. These high-performance indoor and/or outdoor photovoltaic modules are achieved using combinations of the novel perovskite precursor and designs for scribing interconnected cells in modules.

Accordingly, the inventors have established perovskite materials tailored to, and PV cells/modules for, indoor applications using all ambient fabrication methodologies. Embodiments of the invention exploiting carbon electrode based perovskite materials employ a new perovskite precursor solution synthesized under ambient conditions, i.e., room temperature, where the precursor can be deposited to form thin films using various methods such as blade, slot-die, and spin coating for example. These methods support exploitation of the novel perovskite materials to large-area devices for industrial applications.

A perovskite recipe with a specific composition allows for the deposition of high-quality films with the use of a rapid vacuum-assisted method to pre-crystallize the film followed by annealing in ambient air, for example at 135° C. for five to ten minutes. Such a process as outlined below yields an improvement in the perovskite morphology and eliminates the use of antisolvent treatment(s) for large-area deposition of the novel perovskite thin films. The rapid vacuum-assisted method is suitable for mass production.

The novel organic-inorganic perovskite materials according to embodiments of the invention provide tunable optoelectronic properties via composition substitution(s) for both ambient light and sunlight absorption scenarios. The novel precursor solution exhibits long-term storage stability which reduced waste, thereby dropping the materials' cost overall within a production bill of materials.

Further, as outlined below the inventors have established device structures that are adjusted as a function of the novel perovskite material employed. The device architecture consists of the photoactive perovskite material disposed between an electron transport layer (n-type) (e.g., tin oxide, SnO₂) and a hole transport layer (p-type) in a design similar to that of PSC 100 in FIG. 1.

Within embodiments of the invention the hole-transporting material is copper (II) phthalocyanine (CuPC). This has a textured morphology which has previously been seen its use limited in PV type applications. However, the inventors have established a design variation wherein the CuPC is employed in combination with a carbon paste as the top electrode eliminating the requirement for the Upper Electrode 160 as a discrete layer of the PV devices. This enhances the charge transport and collection of photogenerated carriers in the device.

Within embodiments of the invention CuPC may be deposited by thermal evaporation but it may also be deposited from solution by slot die or blade coating methods as well as others. Within the following description emphasis is placed on two perovskite materials (also referred to as a solution as these materials are typically deployed in solution or ink form) which differ in their caesium bromide (CsBr) content. However, it would be evident that these represent just two embodiments of perovskite materials according to embodiments of the invention having the formula FA_{X}Cs_{Y}Pb(I_{1-Z}Cl_{Z}), where X, Y and Z can range from 0.00001 to 3 respectively.

One perovskite material according to an embodiment of the invention does not contain caesium bromide (CsBr) and exhibits a higher efficiency with a HTL layer (namely, CuPC layer) whilst the other perovskite material with defined CsBr content operates without an HTL. As noted above CuPC typically exhibits a surface morphology that limits the contact surface area between the perovskite material and the upper electrode. The inventors established that employing a carbon paste in conjunction with the CuPC, which can be simply deposited on the perovskite film by screen painting prior to deposition of the CuPC, allows for this surface morphology to be accommodated” improving the performance of PVs employing CuPC as the HTL in conjunction with the CsBr free perovskite material and eliminating the requirement for the Upper Electrode 160 as a discrete layer of different material, e.g. gold, with its additional processing step(s).

Within proof of concept devices modules with a pair of cells and with only carbon as the top electrode exhibited an open-circuit voltage of over 2 V. Without encapsulation these modules stored under ~22° C. in relative humidity between 30-40% exhibited a promising shelf lifetime. With encapsulation, the inventors expect stability sufficient for the commercialization of these perovskite modules. Furthermore, as described below, modules exploiting novel perovskite materials are implemented using scribing to achieve complete isolation of the individual cells and further to interconnect the cells in series and avoid short-circuiting within the devices. Importantly, the carbon electrode based perovskite devices show great capability due to their low-cost production and exceptional stability compared to their metal electrical contact counterparts exploiting electrode materials such as gold. Embodiments of the invention support upscaling of manufacturing offering potential for large-area perovskite modules at low cost.

### New Perovskite Materials

As noted above the inventors have established a family of novel inventive perovskite precursor inks that can be prepared under ambient conditions for various device applications. The perovskite ink formulation is FA_{X}Cs_{Y}Pb(I_{1-Z}Cl_{Z}), where X, Y and Z can range from 0.00001 to 3 respectively.

Within initial developments the inventors established different precursor perovskite inks within this family by dissolving organic and inorganic solutes in a mixture of organic solvents, for example N,N′-dimethylformamide (DMF), and N-Methyl-2-pyrrolidone (NMP). Within the exemplary fabrication processes described below a 5:1 volume/volume ratio of DMF and NMP was used as the main solvents. It would be evident that other organic solvents such as dimethyl sulfoxide (DMSO), acetonitrile (ACN), and γ-butyrolactone (GBL), for example either discretely or in combination can also be used with different volume ratios.

To establish a precursor solution for a perovskite composition according to an embodiment of the invention having a bandgap chosen for outdoor PV cells/modules, 0.212 M of cesium chloride, 1.284 M of formamidinium iodide, 1.338 M of lead iodide and 0.269 M of lead chloride were prepared dissolved within the DMF:NMP solvent to a total volume of 600 microliters. The solution was left on a magnetic stirrer for continuous stirring for periods between 1 hours and 24 hours at room temperature. Subsequently, a 0.45 μm polytetrafluoroethylene (PFTE) filter was employed to filter the stirred solution yielding a clear yellow colored perovskite ink. This ink is denoted as OPV520 within the following description and figures. A similar perovskite solution can be obtained by varying the concentration of the solutes or incorporating other dopants.

To establish a precursor solution for a perovskite composition according to an embodiment of the invention having a bandgap chosen for indoor PV cells/modules, lead bromide (PbBr₂) at different concentrations between 0.1 M and 0.5 M was added to the precursor described above, continually stirred for 1-24 hours on a magnetic plate at room temperature before filtering to yield the final ink. Typically, the inventors established, to obtain high voltages in the PV cells/modules, a 0.363 M concentration of lead bromide was utilized in the solution preparation. This ink is denoted as IPV570 within the following description and figures. In other instances, the inventors synthesized precursors that can be used to fabricate indoor solar cells/modules without the need for a hole-transport layer (HTL). In such instances, cesium bromide of molar concentrations between 0.1 to 10 M (in a particular instance the inventors employed 0.15 M) was introduced into the IPV570 solution which was then stirred at room temperature followed by filtration. The devices and materials for which results are presented below and as referenced in the Figures were synthesized in ambient air at room temperatures between 20° C. and 23° C. and at relative humidities between 20% and 45%.

These perovskite inks were then deposited onto cleaned conductive substrates or atop pre-deposited transport layers to fabricate the devices. The inks are compatible with various deposition methods including blade coating, spin coating, drop casting, slot-die coating, ink-jet printing, Roll-to-Roll deposition, spray coating, etc., Moreover, the chemical compositions, molar concentrations, and organic solvents used in this invention were selected for compatibility with the fabrication of large-area devices without requiring further dilution of the ink to meet the rheological requirements for deposition methods such as slot-die coating. The viscosity of the ink can be fine-tuned to mitigate challenges related to such deposition methods.

The perovskite inks according to embodiments of the invention are stable after long periods of storage at room temperature. For instance, devices fabricated over several months from a common precursor batch yielded similar device performance as the one made from the fresh one. This is a significant benefit of embodiments of the invention. Within the prior art most perovskite inks are not stable such that regular fabrication of new precursor solutions is required over time.

However, embodiments of the invention in common, with those previously established by the inventors of composition FA_{X}MA_{Y}CS_{Z}Pb_{Y}I_{M}SCN_{Q}Br_{N} (as described within PCT/CA2020/050809, where X, Y, Z, M, V, Q, N may each range between 0.0001 to 3 respectively), can be processed under ambient conditions whilst the inks can be stored and used over extended periods of time. These advantages, the inventors believe, will enable commercialization of the perovskite inks themselves as well as PV cells/modules exploiting novel perovskite inks themselves and systems employing PV cells/modules exploiting novel perovskite inks.

Within embodiments of the invention substrates supporting deposition of inventive perovskite inks for PVs exploiting these novel perovskite inks may include, but not be limited to, indium-doped tin oxide (ITO), a flexible polymer substrate, polyethylene terephthalate (PET), and a polyimide film (e.g. Kapton).

Within embodiments of the invention hole transport materials compatible with the inventive perovskite inks for use within PVs exploiting these novel perovskite inks may include, but not be limited to, copper (II) phthalocyanine (CuPC), N²,N²,N²′,N²′,N⁷,N⁷,N⁷,N⁷-octakis (4-methoxyphenyl)-9,9′-spirobi[9H-fluorene]-2,2′,7,7′-tetramine (Spiro-OMeTAD), copper thiocyanate (CuSCN), copper iodide (Cul), poly(triaryl amine), poly[bis(4-phenyl) (2,4,6-trimethylphenyl)amine] (PTAA) and poly(3,4-ethylenedioxythiophene) polystyrene sulfonate (PEDOT·PSS).

Within embodiments of the invention electron transport materials compatible with the inventive perovskite inks for use within PVs exploiting these novel perovskite inks may include, but not be limited to, titanium dioxide (TiO₂), zinc oxide (ZnO), [6,6]-phenyl-C61-butyric acid methyl ester (PCBM), bismuth iron oxide (BiFeO₃ also known as BFO), and a bilayer of both TiO₂ and SnO₂.

Within embodiments of the invention interfacial layers compatible with the inventive perovskite inks for use within PVs exploiting these novel perovskite inks in order to suppress recombination within the devices may include, but not be limited to, potassium chloride, magnesium oxide, aluminum oxide (AlOx, Al₂O₃), lead sulfide, and molybdenum oxide.

Within embodiments of the invention contact electrodes compatible with the inventive perovskite inks for use within PVs exploiting these novel perovskite inks may include, but not be limited to, gold, silver, aluminum and carbon. The thickness of an electrode, may for example, vary between 20 nm and 300 nm. Within PVs as fabricated by the inventors 80-100 nm of gold or between 10 μm and 20 μm carbon were employed.

### Perovskite Thin-Film Deposition and Characterization

Within exemplary embodiments of the invention a device architecture employed was:
Lower Electrode (FTO);
ETL (SnO₂);
Perovskite (subsequently referred to as PVK);
HTL (CuPC); and
Upper Electrode (Carbon).

Within an exemplary manufacturing process the ETL (SnO₂) and perovskite (PVK) were deposited by blade coating (BC) whilst the HTL (CuPC) and Upper Electrode (carbon) were thermally evaporated and screen painted, respectively. Different parameters of the BC process (e.g. coating speed, gap height between the blade and the top of the substrate, and the volume of solution dropped) were studied to optimize those layers.

For SnO₂, the volume of the solution was varied between 10 μl and 100 μl depending on the coated area of the FTO upon the substrate, which was varied between 10 cm² and 50 cm². The (SnO₂) layers were annealed between 150-180° C. for one hour in ambient air to crystallize the films, although other annealing conditions may be employed without departing from the scope of the invention.

The SnO₂ layer was pre-treated with potassium chloride using the same BC method followed by annealing at 100° C. for 15-20 minutes. This surface pre-treatment helps passivate the interface between the SnO₂ and PVK. At the same time, annealing the PVK film allows the potassium to diffuse into it thereby reducing defect sites. It would be evident that other pre-treatments and annealing conditions may be employed without departing from the scope of the invention.

The volume of perovskite solution was also adjusted between 10 μl and 100 μl depending on the desired thickness and substrate size. After deposition of the PVK, the PVK was pre-crystallized using a rapid vapor-assisted solution process (VASP) and annealed at 135° C. for between 7 to 10 minutes. Within an exemplary embodiment the VASP process comprised placing the substrate coated with PVK into a vacuum chamber which was pumped down to evaporate any remaining solvent within the PVK film. Depending on the relative humidity of the ambient air, the VASP time process was adjusted to between 20 second and 120 seconds whilst the annealing time and temperature were tuned between 5 minutes to 10 minutes and 100° C. to 150° C., respectively. To ascertain the optimum or preferred film process, the inventors employed different characterization methods, in order to establish deposition parameters for high quality compact PVK films.

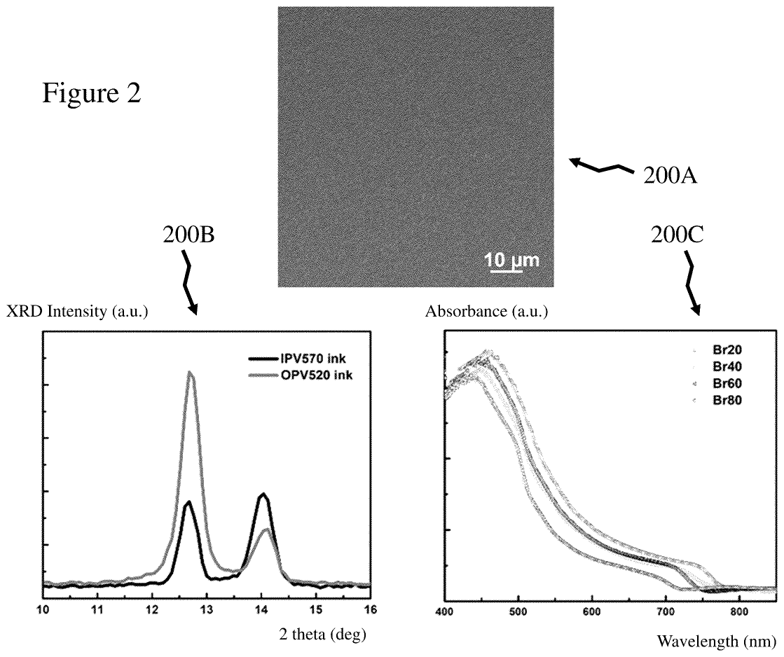

Referring to FIG. 2 in first Image 200A an exemplary scanning electron microscopy (SEM) image is depicted. This being obtained with a TESCAN VEGA-4 LMU SEM. Second Image 200B depicts an X-ray diffraction (XRD) pattern of a deposited film, acquired using a Malvern Panalytical Aeris-DY1097. Third Image 200C depicts UV-visible absorption spectra for PVK films acquired using PerkinElmer UV/vIS Lambda 365. These spectra being for PVK films with varying levels of bromine. These films, denoted as Br20, Br40, Br60 and Br80 vary in bromine from 20 to 80 mg of PbBr₂ in the different PVK solutions.

### Device Architectures and Scribing Patterns

In order to enhance PV cell performance the inventors varied the thickness of the SnO₂ layer, the PVK film, and the thermally evaporated CuPC. The thickness of the blade coated SnO₂ was varied through the number of passes of different concentrations of the SnO₂ solutions. The PVK films varied by using different volumes and coating speeds resulting in different thicknesses of the PVK active layer of the PVs.

The inventors note that for PV devices where the perovskite solution contained CsBr, the best performance was obtained without use of an HTL. In other words, the carbon paste was directly screen painted on the PVK film. To use an HTL, a thin layer between 40 nm to 150 nm of CuPC worked well. This implies the incorporation of CsBr into the perovskite ink can lead to the fabrication of even lower-cost devices that are comparably efficient.

Exemplary PVK PV modules were produced by serially connecting different PV cells within a common module, i.e., the serially connected cells all shared a common substrate. In order to form such a serially connected PV module from PV cells, the top electrode of a first cell should be connected to the lower electrode of a second cell, and so on. Within this specification the inventors refer to a PV module as being an arrangement of two or more PV cells upon the same common substrate (i.e., monolithically integrated) connected in this manner.

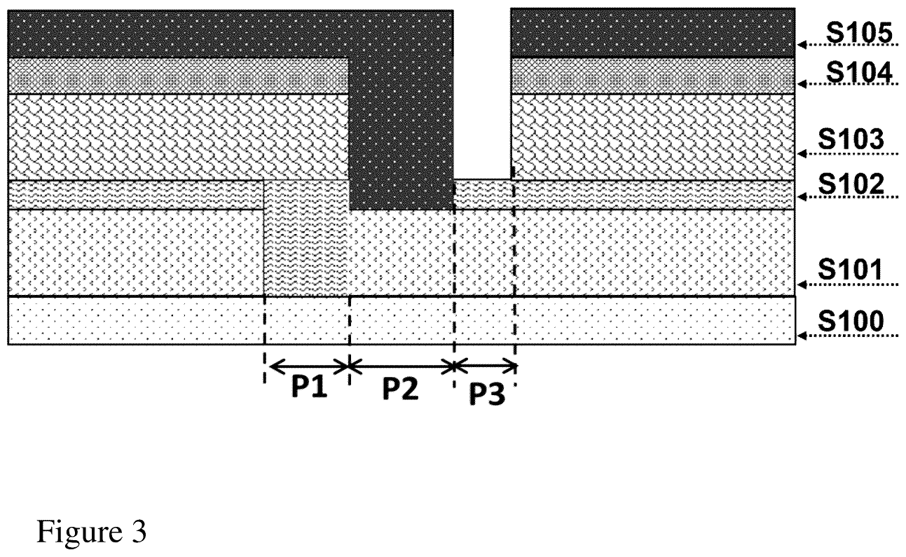

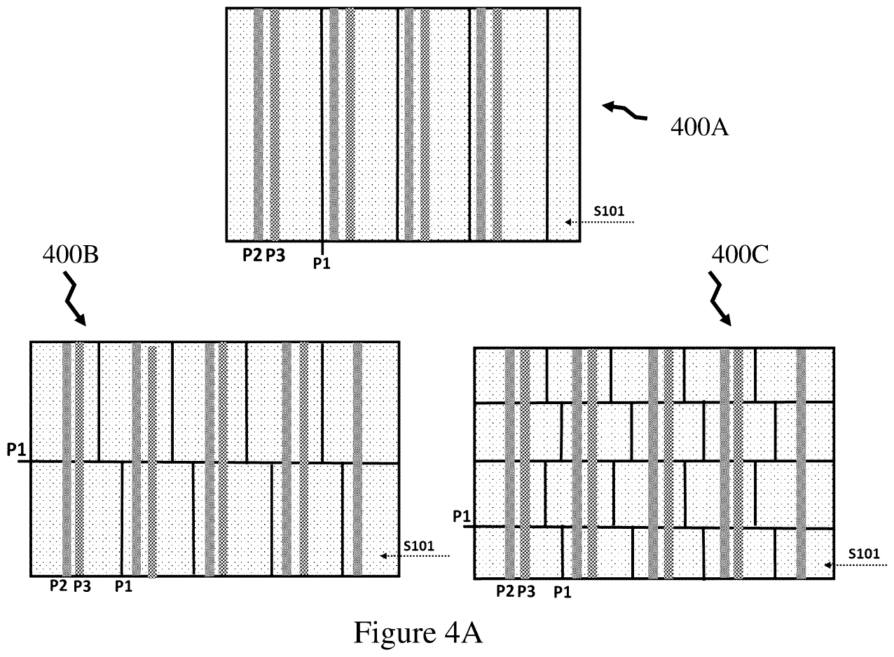

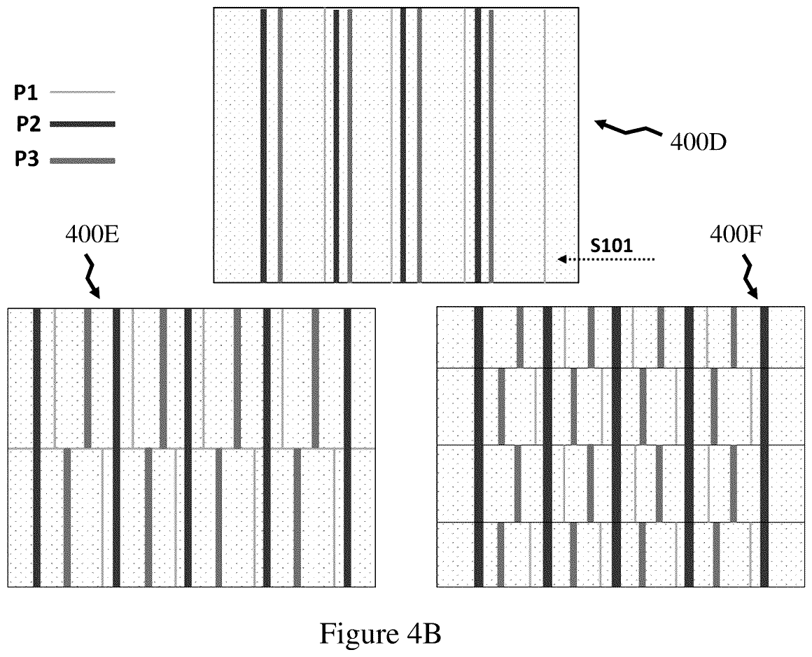

Exemplary schematics of PV module of different module architectures are depicted within FIGS. 3, 4A and 4B. Referring initially to FIG. 3 there is depicted a cross-section structure of the various layers wherein these are:
Glass (S100);
FTO (S101);
Electron Transport Material (ETM) (S102);
Perovskite (S103);
Hole Transport Material (HTM) (S104); and
Top Contact (S105).

Within embodiments of the invention the ETM (S102) is an n-type material such as compact TiO₂, compact SnO₂ and/or mesoporous TiO₂. The PVK (S103) thin film is deposited atop the ETM (S102). The HTM (S104) within embodiments of the invention is a p-type layer of CuPC, Spiro-OMeTAD or CuSCN. The Top Contact (S105) may be within embodiments of the invention be carbon or gold for example.

As depicted in the cross-section of FIG. 3 a standard scribing scheme is depicted comprising three scribing steps during the manufacturing, which are P1, P2, and P3. All scribing can be done either by laser or mechanically. P1 is the first scribing step that separates the FTO (S101) into different cells while the P2 scribing is performed before the deposition of the top electrode, e.g., carbon paste, to provide access to the FTO (S101) of the different cells after the deposition of ETM (S102), e.g., SnO₂, Perovskite (S103), and HTM (S104), e.g. CuPC. Subsequent, to deposition of the Top Contact (S105), e.g. a carbon electrode, the P3 scribing separates the top electrodes of the different cells within the module. Optionally, processing for each of P1, P2 and P3 may be via photolithography/etching rather than through laser scribing or mechanical scribing. Photolithography/etching may be employed for one or more steps for forming P1, P2 and P3.

Optionally, a mask may be employed for screen-printing or other printing of the Top Contact (S105) where the Top Contact (S105) is formed using a carbon paste or other conductive material compatible with such a processing step. With screen-printing or similar removal of the mask after the screen painting of the carbon will also separate the top electrode of the different cells. If the masking material is electrically isolating to the desired level then it may be left in place if excess carbon paste can be removed by another means.

Referring to first Image 400A, the processing of P1, P2 and P3 results in a series of discrete PV cells which must then be serially connected. However, referring to FIG. 4A in second and third Images 400B and 400C respectively there are depicted architectures according to embodiments of the invention wherein the resulting PV cells after connected in series. Comparing second and third Images 400B and 400C to first Image 400A the P2 and P3 scribing steps are the same as those within first Image 400A but the P1 scribing differs. The inventors refer to the architectures depicted in second and third Images 400B and 400C as “zigzag” architectures.

As evident between second and third Images 400B and 400C the P1 scribing changes so that it alternates according to the number of divisions of the cell perpendicular to the scribing line. In second Image 400B there is 1 horizontal P1 division and 2 vertical P1 scribe lines, 1 per horizontal row of cells. In third Image 400C there are 3 horizontal P1 divisions with 4 vertical P1 scribe lines, 1 per horizontal row of cells.

An advantage of the scribing patterns depicted in second and third Images 400B and 400C is that they allow for an enhancement of the output voltage. Accordingly, in second Image 400B the module is divided into 4 cells connected in series. If each cell generates ~1 V then the design in second Image 400B yields a PV module giving ~8 V via 8 cells with the zigzag design according to an embodiment of the invention rather than ~4 V with the design in first Image 400A of the prior art. In third Image 400C the result is 16 cells yielding a PV module operating at ~16 V which are all connected in series within the module whilst maintaining the output power.

Referring to FIG. 4B there are depicted fourth to sixth Images 400D to 400F respectively wherein fourth Image 400D is again a design according to the prior art whilst fifth and sixth Images 400E and 400F depict “zigzag” architectures according to embodiments of the invention with an alternate design methodology wherein the alternating scribe pattern is implemented within the horizontal P1 scribe and vertical P2 scribe sequences rather than within the horizontal and vertical P1 scribe sequences.

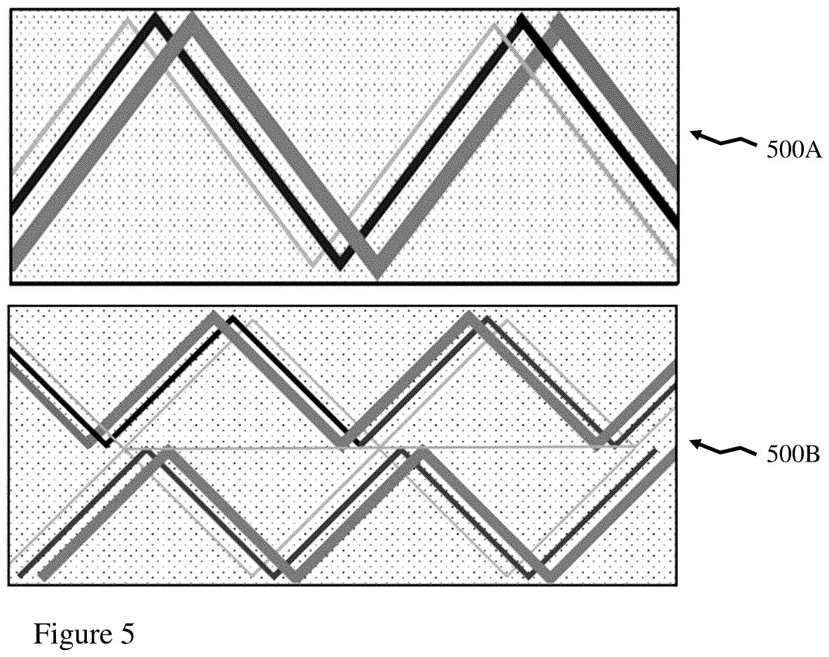

Now referring to FIG. 5 there are depicted first and second Images 500A and 500B of alternate “zigzag” architectures exploiting scribe patterns for providing inherently connected PV cells within a module through the scribing pattern, in common with second and third Images 400B and 400C in FIG. 4A and fifth and sixth Images 400E and 400F in FIG. 4B.

Within current PV manufacturing laser scribing is the most common technology for perovskite modules since it is quoted as providing low-cost manufacturing, high production speed and a high resolution thereby providing a high geometrical fill factor ratio (i.e., active area/dead area or active area/module). Further, this emphasis on fill factor is prevalent in small area PVs.

However, this laser scribing process has to be optimized to avoid degradation of perovskite layer, due to its thermal and light sensitivity. Accordingly, this becomes critical when the P2 scribing is performed as it can lead to decomposition of the perovskite and the formation of lead iodide (PbI₂) at the edges of the scribe lines. Furthermore, with this prior art scribing methodology the perovskite layer is exposed both to the metal electrode and to the ambient environment which affects the stability of the overall module or requires encapsulation/packaging within an inert atmosphere.

Direct contact of top electrode with perovskite induces the metal-migration and thus the degradation of the perovskite. Whilst within the prior art there are multiple techniques reported to overcome this issue, including but not limited to introduction of a molybdenum oxide (MoOx) interlayer between hole transport layer (HTL) and the metal electrode, usage of multiple interlayers, atomic layer deposition (ALD) of an ultra-thin layer of Al₂O₃ directly on the perovskite to protect the perovskite layer, chemical inhibition using amine-mediate metal-oxide systems, replacing the metal with semitransparent ITO back electrodes, introducing a diffusion barrier inside the P2 scribe, and depositing the HTL directly on electron transporter layer (ETL) without any scribing. However, all these approaches have disadvantages with respect to an increase of manufacturing complexity leading to increased cost of the modules and reduced conversion efficiencies.

In contrast, the methodologies presented in second and third Images 400B and 400C in FIG. 4A, fifth and sixth Images 400E and 400F in FIG. 4B, and first and second Images 500A and 500B in FIG. 5 provide for improved processing and device performance whilst yielding serially connected PV cells without any additional connections being made.

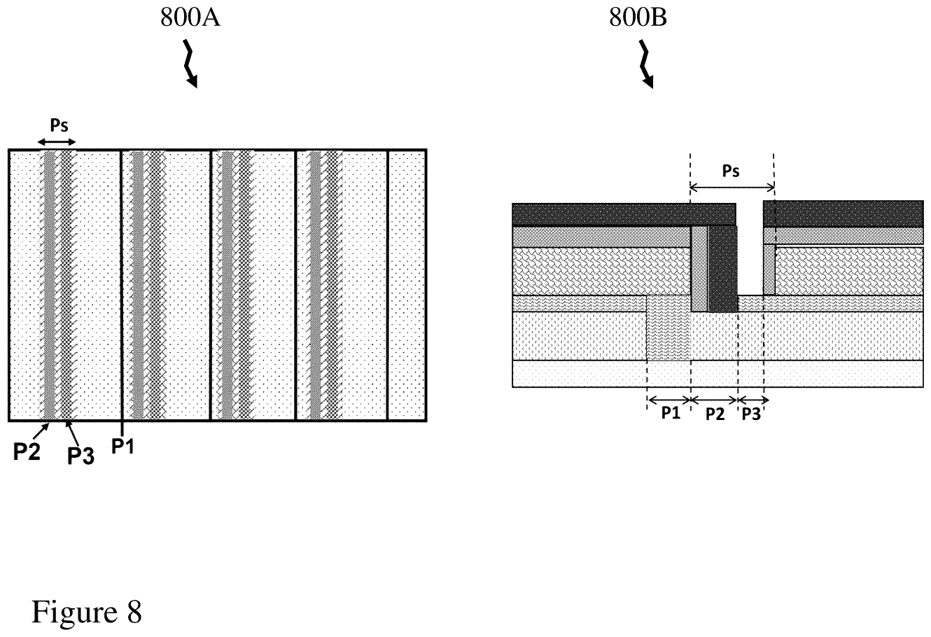

The scribing of each set of scribe lines, i.e., P1, P2 or P3, can be carried out mechanically but also using a laser method as described and depicted below with respect to FIG. 8. Within this alternate design/manufacturing methodology an initial scribe line, Ps, is formed and then the P2 and P3 scribes are established within this common scribe, Ps. Benefits of exploiting this design methodology are:
with mechanical scribing of Ps, decomposition of the perovskite and the formation of PbI₂ are avoided;
no direct contact between the metal electrode and perovskite occurs thereby limiting the degradation of the perovskite; and
there is no direct exposition of the perovskite to the ambient atmosphere.

This last benefit is particularly important as it allows for unencapsulated PV devices with enhanced stability and lower cost.

### Device Performance

In order to assess the photovoltaic performance of the new novel perovskite materials and PV architectures the inventors incorporated the perovskite materials as absorber layers in photovoltaic devices (targeted for outdoor and indoor applications) in view of the ease with which the perovskite ink can be tailored for different applications. PV cells with different top electrode materials were employed in combination with both rigid and flexible substrates.

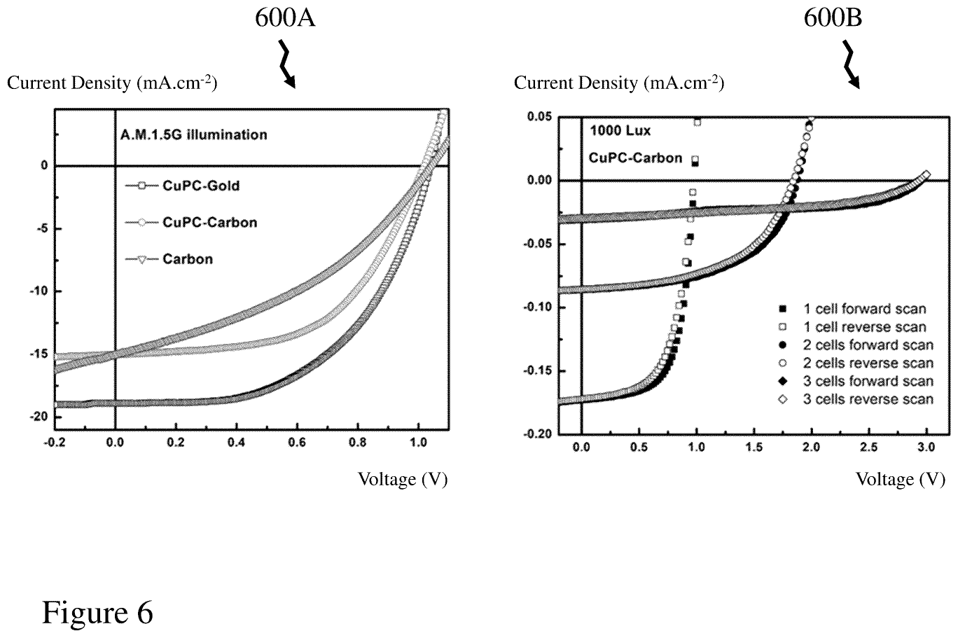

FIG. 6 depicts the results of devices fabricated upon rigid substrates with FTO as the Lower Electrode S101. First Image 600A depicts the current-voltage characteristics of the PV cells fabricated using the OPV520 ink with only carbon, CuPC plus carbon and CuPC plus gold, respectively, as the top electrodes. The CuPC with gold devices under A.M.1.5G illumination outperformed the devices employing carbon only or CuPC and carbon. However, the performance of the device with CuPC and carbon is still good and offers an advantage in terms of cost as carbon is lower cost against gold. An efficiency of 12% for a device made with carbon is still beneficial considering the low resistivity of carbon although this resistivity difference could be the cause of the decrease in efficiency.

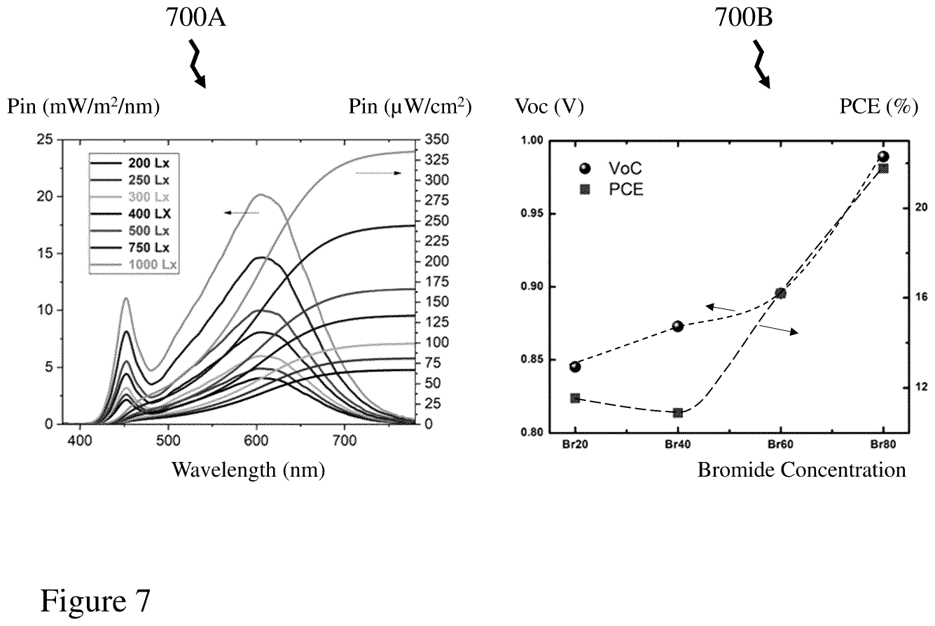

Based on this outcome, the inventors fabricated PV modules using the IPV570 perovskite ink for indoor with CuPC plus carbon as the top electrode. These devices performed well under 1000 Lux irradiance with efficiency of approximately 28% for a single cell and approximately 22% for modules. The results for single, dual and triple PV modules being depicted in second Image 600B in FIG. 6. The spectrum of the lamp employed in performing these measurements is depicted in first Image 700A in FIG. 7.

Table 1 below summarizes the obtained values of the photovoltaic parameters (J_{sc}: short circuit current density; V_{oc}: open circuit voltage; fill factor (FF) and power conversion efficiency (PCE) of the devices. Second Image 700B depicts the variation of voltage and power conversion efficiencies for the indoor devices using the OPV520 perovskite ink which increases as the bromide content is increased in the perovskite solution.

It would be evident, that both of the OPV520 and IPV570 inks, can therefore be tuned by chemical engineering to achieve efficient PV devices.

TABLE 1
Summary of Performance for PV Devices According
to Embodiments of the Invention

| | | | | |
|---|---|---|---|---|
| | J_{sc} | Fill | V_{oc} | PCE |
| Cell Type | (mA/cm²) | Factor (%) | (V) | (%) |

Outdoor Devices (OPV520 Ink)

| | | | | |
|---|---|---|---|---|
| Cell - Only Carbon | 15.5 | 39.8 | 1.04 | 9.1 |
| Cell - CuPC + Carbon | 15.0 | 55.6 | 1.02 | 12.2 |
| Cell - CuPC + Au | 18.9 | 53.6 | 1.04 | 15.1 |

Indoor Devices (Module) (IPV570 Ink)

| | | | | |
|---|---|---|---|---|
| 1 Cell-CuPC + Carbon | 0.17 | 64.9 | 0.98 | 27.5 |
| 2 Cells-CuPC + Carbon | 0.85 | 54.4 | 1.89 | 22.0 |
| 3 Cells-CuPC + Carbon | 0.03 | 50.6 | 2.95 | 13.0 |

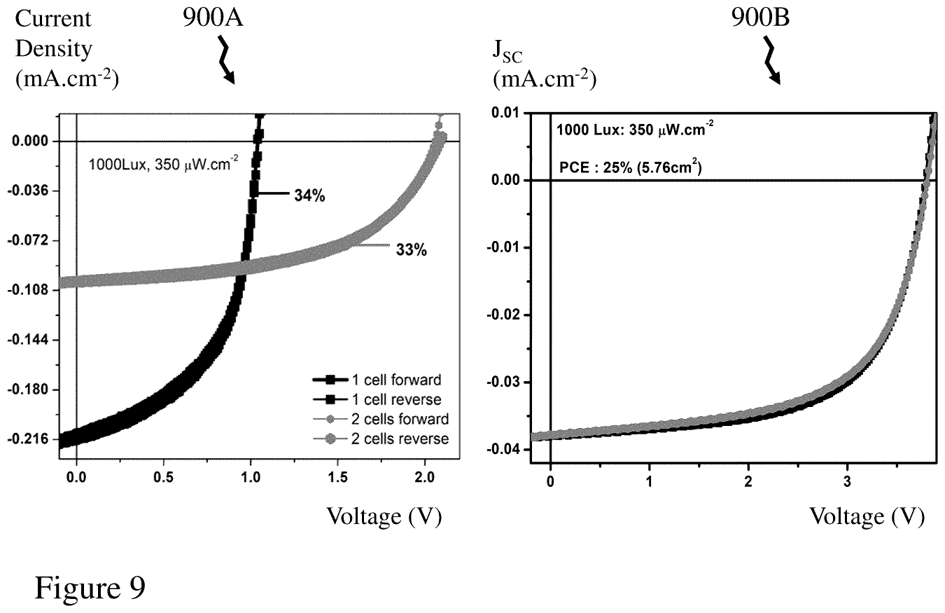

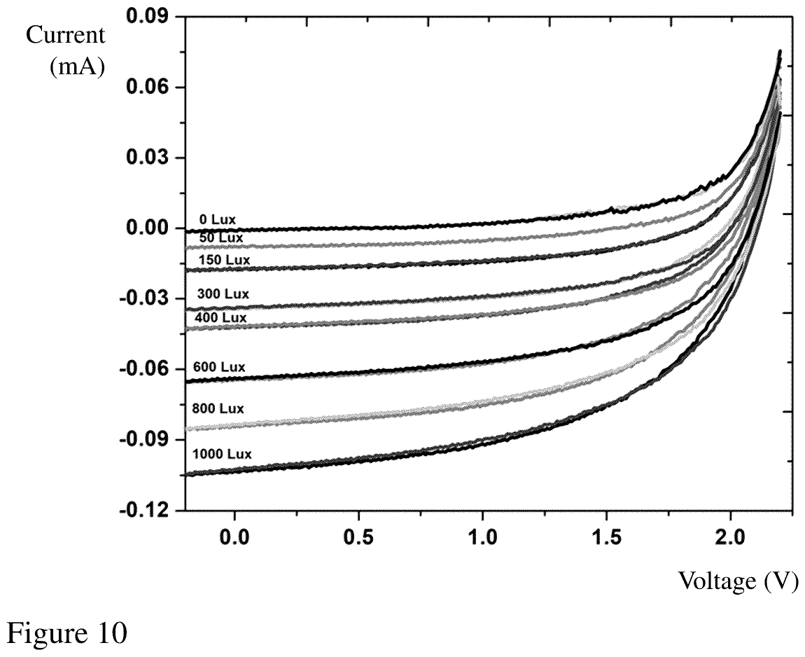

Now referring to Table 2 below there are presented results for indoor perovskite modules according to embodiments of the invention. FIG. 9 depicts J-V measurements under 1000 Lux illumination for indoor PV devices made with inventive IPV570 perovskite ink. In first Image 900A these are depicted for modules with 1 cell and 2 cells respectively. Second Image 900B depicts a module with 4 cells connected in series. The same PV modules were subjected to different irradiance from 50 Lux to 1000 Lux and the J-V plots are shown in FIG. 10.

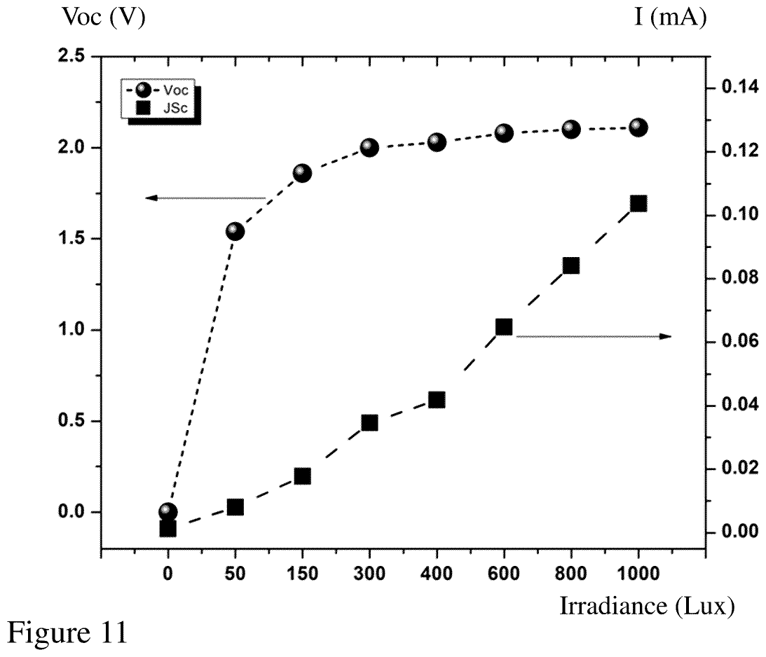

At low irradiance of 50 Lux, the devices registered a Voc as high as 1.5 V. The extracted Voc and Jsc for the module measured under different irradiance from 50-1000 Lux illumination for indoor devices made with IPV570 perovskite as shown in FIG. 11. This shows that the modules exhibits a Voc of 2 V for two-cells in series which remains almost unchanged for illuminations up to 300 Lux and then decreases to approximately 1.5 V at 50 Lux. The induced photocurrent as expected increases with increased irradiance.

TABLE 2
Performance Summary of PV Devices According
to Embodiments of the Invention

| | 1 cell-CuPC + | 2 cells-CuPC + |
|---|---|---|
| J-V Parameters | Carbon | Carbon |
| Power Conversion Efficiency (%) | 33.7 | 32.7 |
| Fill Factor (%) | 54.0 | 55.5 |
| Short Circuit Current, Jsc(mA/cm²) | 0.22 | 0.11 |
| Open Circuit Voltage, Voc (V) | 1.04 | 2.08 |

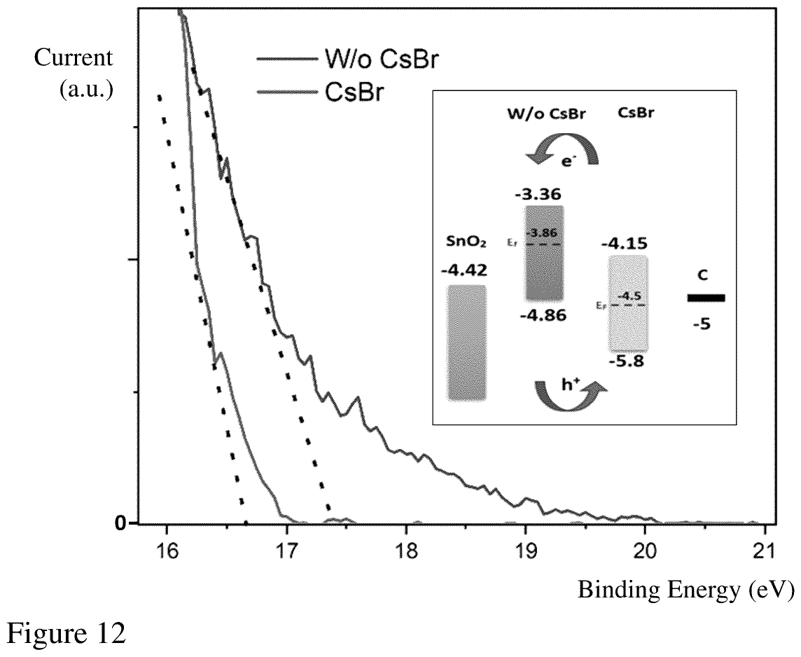

Now referring to FIG. 12 there are depicted ultraviolet photoelectron spectroscopy (UPS) spectra for inventive perovskite inks with and without CsBr. The insert illustrates the band alignment between the perovskite and the transport layers employed within the PV cell. As evident from FIG. 12 perovskite films without CsBr are more p-type than those with CsBr. Accordingly, there is no need for a hole transport material with perovskite inks with CsBr and PV cells fabricated with just carbon work efficiently without the use of hole-transporting material.

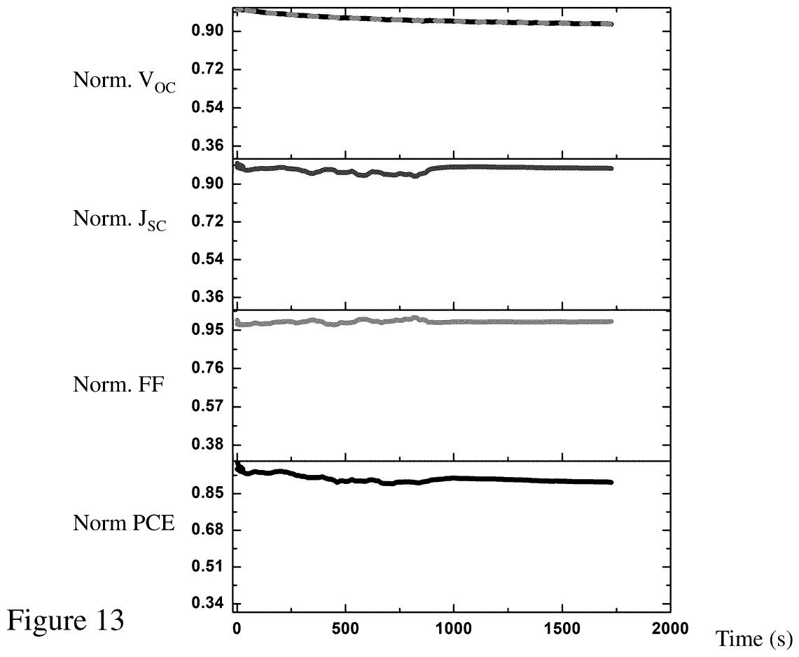

Referring to FIG. 13 there are depicted time plots for VOC, JSC, fill factor and photonic conversion efficiency for a single PV cell subjected to continuous illumination at 1000 Lux for two hours. The devices were measured under ambient laboratory conditions. The PV parameters retained their performance after exposure for the whole duration. Thus, the inventive perovskite inks and their devices exhibit long-term stability which is vital for the commercialization of the technology.

It would be evident that the results and methods described above with respect of the manufacture and deposition of novel perovskite materials according to embodiments of the invention have been performed within a research laboratory environment and accordingly that in high volume manufacturing that one or more additional materials may be required in order to facilitate their manufacture and use.

For example, with respect to further stabilization of the perovskite solution these one or more additional materials may include the user of small molecule acceptors (SMAs). Such SMAs may include, but not be limited to, ITIC (2,2′-[[6,6,12,12-Tetrakis(4-hexylphenyl)-6,12-dihydrodithieno[2,3-d:2′,3′-d′]-s-indaceno[1,2-b:5,6-b′]dithiophene-2,8-diyl]bis[methylidyne (3-oxo-1H-indene-2,1(3H)-diylidene)]]bis[propanedinitrile]) derivatives which can be dissolved in solvents such as chloroform, chlorobenzene or dichlorobenzene.

For example, with respect to the fabrication of large-scale and flexible devices other deposition techniques such as screen printing, roll-to-roll printing, inkjet printing, slot-die printing, spray coating etc. may be employed which could require some modifications of the viscosity of the perovskite solution for example by adjusting the concentration of the solutes or adding the one or more additional materials to adjust viscosity.

For example, with respect to the wettability and surface coverage of the perovskite solution onto substrates this may require the addition of one or more surfactants. For example, one such surfactant could be polyethylene glycol tert-octylphenyl ether.

For example, with respect to manufacturing the one or more additional materials may include inert particles of predetermined dimensions, e.g. nanorods, microrods, microspheres etc. to define a layer thickness with some manufacturing processes such as screen printing for example.

Embodiments of the invention allow for devices exploiting novel perovskite films can be arranged in different device architectures in either planar or inverted device architecture. Typically, the perovskite thin film deposited forms a planar architecture with an n-type (such as titanium dioxide, TiO₂ compact or mesoporous microstructure, PCBM) and a p-type (Spiro-MeOTAD, copper thiocyanate, or PEDOT·PSS) layers, and can be formed on both rigid (e.g. glass) and flexible substrates. The conductive glass-coated substrates can be a fluorine-doped tin oxide (FTO) or indium tin oxide (ITO). In another aspect, the tandem cells comprise of a bottom cell which may be a silicon substrate or textured silicon substrates. A flexible substrate can be any conductive polymer such as PET, and polyimide films.

Embodiments of the invention can comprise of the novel halide perovskite layer and carbon-based materials such as single-wall carbon nanotube and graphene layers.

Embodiments of the invention a solar cell device fabrication method can comprise of spin-coating of the n-type layer onto a transparent conductive substrate such as FTO or ITO, followed by spin coating of the halide perovskite thin film, then the p-type material is spin-coated from solution atop the photoactive layer and finally a deposition of desirable top metal electrodes such as Au or Ag by sputtering or an evaporation method.

Embodiments of the invention present a similar method for producing light-emitting diodes in ambient conditions. In this embodiment, a thin layer of the halide perovskite is sandwiched between a p-type and n-type layers.

The foregoing disclosure of the exemplary embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and remain within the spirit and scope of the present invention.

What is claimed is:

1. A method of forming a photovoltaic device comprising:
depositing one or more first layers of the photovoltaic device to form a lower portion of the photovoltaic device;
depositing a perovskite film to form an active layer of the photovoltaic device; and
depositing one or more second layers of the photovoltaic device to form an upper portion of the photovoltaic device; wherein
the perovskite film has the composition FA_{X}Cs_{Y}Pb(I_{1-Z}Cl_{Z}) where X, Y and Z range from 0.00001 to 3 respectively.

2. The method according to claim 1, wherein
the perovskite film is formed from a double cation perovskite solution.

3. A method of forming a precursor comprising:
dissolving a number of individual components in one or more organic solvents; and
dissolving an additive with the number of individual components; wherein
the precursor provides for a doped perovskite film when processed onto a substrate;
the precursor is a double cation perovskite solution;
the precursor allows formation of doped perovskite films in ambient conditions; and
the perovskite film has the composition FA_{X}Cs_{Y}Pb(I_{1-Z}Cl_{Z}) where X, Y and Z range from 0.00001 to 3 respectively.

4. A device comprising:
a perovskite film forming the active layer of the device; wherein
the perovskite film has the composition FA_{X}Cs_{Y}Pb(I_{1-Z}Cl_{Z}) where X, Y and Z range from 0.00001 to 3 respectively.

5. A method of fabricating a photovoltaic device comprising:
forming a lower conductive layer;
forming an active layer upon the lower conductive layer which generates an electrical current in dependence upon optical illumination within a predetermined wavelength range illuminating the active layer;
forming an upper conductive layer upon the active layer;
establishing a series of first scribe lines to isolate a first plurality of regions where each first scribe line of the series of first scribe lines penetrates down through the lower conductive layer;
establishing a series of second scribe lines to isolate a second plurality of regions where each second scribe line of the series of second scribe lines penetrates down through at least the active layer but not the lower conductive layer; and
establishing a series of third scribe lines to isolate a third plurality of regions where each third scribe line of the series of third scribe lines penetrates down through the active layer and upper conductive layer.

6. The method according to claim 5, wherein
a first subset of the series of first scribe lines extend in a first direction;
a second subset of the series of first scribe lines extend in a second direction perpendicular to the first direction where each first scribe line of the series of first scribe lines extends between a first scribe line of the first subset of the series of first scribe lines and an adjacent first scribe line of the first subset of the series of first scribe lines;
each second scribe line of the series of second scribe lines are in the second direction and extend across the first subset of the series of first scribe lines; and
each third scribe line of the series of third scribe lines are in the second direction, extend across the first subset of the series of first scribe lines, and are offset from a second scribe line of the series of second scribe lines.

7. The method according to claim 5, wherein
a first subset of the series of first scribe lines extend in a first direction;
a second subset of the series of first scribe lines extend in a second direction perpendicular to the first direction between a first scribe line of the first subset of the series of first scribe lines and an adjacent first scribe line of the first subset of the series of first scribe lines;
the series of second scribe lines extend in the second direction where each second scribe line of the series of second scribe lines extends between a first scribe line of the first subset of the series of first scribe lines and an adjacent first scribe line of the first subset of the series of first scribe lines;
each third scribe line of the series of third scribe lines are in the second direction, extend across the first subset of the series of first scribe lines, and are offset from a predetermined subset of the series of second scribe lines.

8. The method according to claim 5, wherein
the series of first scribe lines are either mechanically scribed or etched;
the series of second scribe lines are either mechanically scribed or etched; and
the series of third scribe lines are either mechanically scribed or etched.
